(19) United States
(12) Patent Application Publication
(10) Pub. No.: US 2005/0117347 A1
(43) Pub. Date: Jun. 2, 2005

(54) Optical lighting device and method to produce lighting devices adopting said optical device

(75) Inventors: Patrizia Melpignano, Moruzzo (IT); Roberto Zamboni, BolognA (IT)

Correspondence Address: STEVENS DAVIS MILLER & MOSHER, LLP, 1615 L STREET, NW, SUITE 850, WASHINGTON, DC, 20036, US

(73) Assignee: Automotive LIghting Rear Lamps Italia SpA, Tolmezzo (UD) (IT)

(21) Appl. No.: 10/507,128

(22) PCT Filed: Mar. 12, 2003
(86) PCT No.: PCT/IB03/00895

(30) Foreign Application Priority Data
Mar. 12, 2002 (IT) US2002A000059

(51) Int. Cl. F21V 5/04

(52) U.S. Cl. 362/309

(57) ABSTRACT

Lighting device and method to make it. The device comprises a light source (11) including a positive electrode (14) and a negative electrode (13) between which a luminescent layer (16, 17) is located. On the outer side of the multi-layer structure there is a substrate (20) which diffuses the light generated by the luminescent layer (16, 17). A lenticular optical element (21) is associated with a face of the substrate (20) and is obtained by means of molding in a single piece in the substrate (20). The optical element (21) consists of micro-lenses (22) each one cooperating with a relative point of light emission (19) to direct and shape the relative ray of light emitted.

### FIELD OF THE INVENTION

The present invention concerns an optical lighting device, used to make integrated electro-optical lighting devices of the multi-layer type.

Such integrated lighting devices comprise at least an outer substrate to irradiate and diffuse the light, at least partly transparent and advantageously of the flexible type, on one face of which an electro-luminescent light source is integrally made, comprising light emitting means of the organic led type (organic light emitting diode, hereafter OLED).

The present invention is characterized in that a lenticular optical micro-element to diffuse the light is made directly and integrally by means of molding on the other face of the flexible and transparent substrate, so as to constitute, with said organic led-type light source, an integrated multi-layer structure as a source/diffuser of light, suitable to achieve particular and desired effects for the emission and direction of the light beams.

The invention also concerns the method to produce integrated lighting devices adopting said optical device.

### BACKGROUND OF THE INVENTION

In the field of production of electric and electronic instruments and apparatuses, it is known to use light emitting devices which comprise led-type electro-luminescent light sources used to make lighting devices, displays, or more generally illuminated display screens.

As is known, leds are devices able to convert electric energy into luminous energy and are therefore able to emit radiant energy in the form of light when they are fed by a suitable electric current.

Applications of this type of light sources are extremely various and can comprise displays or monitors for calculators, screens for portable or fixed telephone systems, screens for televisions or measuring instruments/indicators, luminous panels, inside lights for rooms, lighting devices in general and other uses.

In the field of automobile or motor vehicle production, both for the instruments on the dashboard inside and for part of the lighting system, this type of led-type light source has sometimes replaced conventional incandescent bulbs, thanks to the particular and appreciated aesthetic effects of multi-point emission which can be obtained.

Leds using conventional semi-conductors have recently been supported and/or replaced by leds which use organic-type film (OLED) obtained with particular compounds which, from the point of view of electric conduction, have characteristics comparable to those of semi-conductors. The possibility of using synthetic organic compounds as a luminescent element has allowed to make lighting devices and displays of smaller size and high resolution, at the same time ensuring high efficiency in the transmission of light, and long duration.

A typical multi-layer light source with leds of this type comprises a negative pole (cathode), possibly made with an alloy of aluminum and indium, at least a luminescent layer made of organic material which also encourages the passage of the charge between the electrodes, a positive pole (anode) normally consisting of a transparent conductive electrode and a transparent substrate to emit the light. Said substrate is advantageously of the flexible type and can be made of glass or transparent plastic.

Between the anode and the transparent substrate there is advantageously a protective layer to prevent infiltrations of air and water in contact with the organic films and the electrodes.

Document JP-A-10-223367 provides a method to produce optical systems by means of the photo-curing system, possibly also by means of exposure through a mask; this method does not allow to obtain the micro-optical systems in a repeatable and industrial manner with the prescribed values of size, since such photo-curing system is a laboratory technique, embodied in an experimental method which is not applicable for serial production.

This document does not teach to make the organic led light source directly on the transparent substrate, since the layers that form the light source (anode, cathode and luminescent layer), are laminated onto the substrate and not made to grow directly thereon.

Moreover, this document provides that the optical systems are produced on a plastic film that is then applied separately to an organic led device (OLED) produced on glass. This method not only increases costs, but also does not guarantee a constant precise positioning of the optical system with respect to the light source.

Document JP-A-09-171892 emphasizes the fact that it uses optical systems essentially of the spherical type coupled with OLED structures.

The optical systems described are all of the refractive type, and in particular are of the type with a refractive distributed index. The Applicant has discovered, on the contrary, that better results, in relation to the aims proposed, are obtained with optical systems of a diffractive type. In addition, said document emphasizes the importance of centering the lenses on the emittent pixels, whereas the Applicant has discovered that better results, in terms of directing and shaping, the beam, are obtained by shifting the centering between the emittent pixel and the micro-optical system, in order to obtain the effect of directing the light in the most convenient and suitable manner to obtain a desired distribution of radiation output from the integrated device.

In general, it must be underlined that the prior art proposes solutions wherein the optical system is applied on the emittent substrate containing the light sources, in order to increase the efficiency of light emission, that is, to increase the percentage of luminous radiation emitted from the front of the device with respect to that which is lost at the sides (see for example also JP-A-04-192290 and JP-A-2001-135477). It is known, in fact, that due to the variation in the index of refraction in the glass/air or plastic/air interface, a mirror effect is determined inside the optical device due to the total reflection of the radiation emitted, so that a high percentage of luminous radiation remains trapped in a sort of wave guide, and consequently the frontal emission is reduced. The presence of a corrugated optical system applied to the emittent face of the substrate, varying the angle of incidence of the incident ray, encourages a better extraction of the light beam from the front zone with fewer losses due to the entrapment of the light because of the wave guide effect. A teaching in this direction also comes from the article “Improvement of output coupling efficiency . . . ” by C. F. Madigan et al., which teaches precisely to apply, by means of lamination, as shown in FIG. 3, a lenticular optical system on an organic substrate of light emission in order to vary the angle of incidence of the ray of light and thus increase the efficiency of emission of the optical device. This document teaches to make a thin layer of transparent micro-lenses in a printed silicon sheet and then laminate it on the glass substrate after the organic leds have been applied.

However, the state of the art does not deal with the problem of directing and shaping the light beam, using said micro-lenses. The application techniques of the micro-lenses, which use applied layers like JP'528, or laminated, as in the article by Madigan et al., which are therefore micro-lenses that are not made directly on the substrate, teach away from the purpose of directing the light beam according to desired angles, since such techniques do not allow to guarantee a micrometric positioning of the individual lens with respect to the relative light source. Nor do such techniques allow to guarantee a precise diversification of the orientation and shaping of the light beam inside the same optical device.

For the same reason, U.S. Pat. No. 6,080,030 does not achieve the purpose set since the lenses are obtained either by applying a layer of ultraviolet cured resin on an emittent substrate, or by implanting ions in the substrate in order to produce a distribution of the refractivity. However, this solution is intended to obtain an image with very pure colors, since every color is refracted in a differentiated manner inside the individual lens, but it does not allow to obtain a desired orientation of the light beam emitted.

US 2002/0141006 does not concern organic led light sources, since it uses conventional leds of an electronic type with a semi-conductor. Such electronic leds, as such, cannot be made directly on the substrate but must necessarily be applied thereto as a distinct element.

Therefore, such conventional light sources, from the point of view of diffusing the light beams produced by the led-type sources, do not have characteristics such as will allow both to achieve appreciable aesthetic effects, and to make said beams able to be oriented and directed so as to cover areas which cannot be reached without using particular optical effects.

The Applicant has devised and embodied the present invention to overcome these shortcomings of the state of the art and to obtain further advantages.

### SUMMARY OF THE INVENTION

The present invention is set forth and characterized essentially in the respective main claims, while the dependent claims describe other innovative characteristics of the invention.

The purpose of the present invention is to achieve light sources to make lighting devices using radiant electro-luminescent devices able to emit and diffuse light beams suitably directed and directable when fed by a suitable electric impulse.

Another purpose is to perfect a method to produce lighting devices which allows to make multi-layer integrated lighting structures, using organic led technology.

The invention can advantageously be used to make lighting instruments in the field of automobiles, both for the lighting system and for the instrument panel inside, although this application is not to be considered in any way restrictive.

In accordance with these purposes, a lighting device according to the present invention comprises a light source consisting of an integrated multi-layer structure with a transparent substrate on one face of which at least a positive and negative electrode to supply electric power are integrally made, between which at least an organic luminescent layer is located, so as to constitute a so-called organic led (OLED).

The substrate is at least partly transparent and is able to diffuse, in a diffractive manner, the light generated by the luminescent layer.

According to a distinctive characteristic of the present invention, a lenticular optical element to diffuse the light beam is made by means of molding on the opposite face of said substrate, with respect to the face where there is the organic led light source, so as to constitute, with said organic led light source, a completely integrated structure to generate, emit and direct the light.

The lenticular optical element consists of a plurality of micro-lenses made directly on said plastic substrate, in a position and number mating with the position of the crossing points between anode and cathode of the light source, so that every lens constitutes an element for the calculated diffusion of the light emitted by each individual light source point.

According to the invention, the lenticular optical element is made directly, by means of a pre-formed mold, on the outer face of the transparent substrate. This embodiment allows to configure the mold so as to obtain, with micrometric precision, the desired effect of directing and shaping the light beam, even lens by lens or zone by zone of the optical device.

The Applicant has verified that a desired effect of shaping the beam is obtained by shifting, for example by some microns, the center, or baricenter in the case of a non-spherical shape, of the lens from the center of the relative pixel which emits the light, so that not only is it not necessary to obtain any centering, but also it is advantageous to avoid it.

The Applicant has also found that, although in general the state of the art teaches to use optical systems of a refractive type since the objective is to increase radiant efficiency, in order to achieve the purpose set it is preferential to use an optical system of a diffractive type.

An optical system of a diffractive type does not compromise the efficiency of the light radiation but allows to obtain the desired characteristics of orienting and directing the light beams according to the desired design specifications.

In one embodiment of the invention, the micro-lenses which constitute the optical element are all alike; according to another solution, the lenses are differentiated according to the zones of the optical element, or even lens by lens, so as to create a desired differentiated effect in the directioning of the individual rays of light according to the design specifications.

In a first embodiment, the molding of the lenticular optical element on a face of the substrate is performed cold whereas, according to a preferential variant, the molding is performed hot.

Obtaining the micro-lenses directly on the plastic substrate by means of molding, and in particular obtaining the micro-optical systems by means of the hot-embossing technique, allows to achieve large quantities of plastic supports industrially and in a repetitive manner, already equipped with the desired micro-optical systems. This would not be possible using the laboratory techniques proposed in the state of the art.

The Applicant has found that this embodiment becomes advantageous using molds having at least the operative layer made of nickel, wherein the impressions to define the optical matrixes, all the same or different from each other, are obtained with the known procedure called “step and repeat”.

In one embodiment of the invention, the molding of the lenticular optical element can be performed either before or after the layers, which make up the light source emitting the light, have already been made to grow on the opposite face of the transparent substrate.

In a preferential embodiment, the lenticular optical element is made of transparent plastic material, with high thermo-forming characteristics.

In a further preferential embodiment, the lenticular optical element has a thickness of between 1 and 100 μm (micron), advantageously between 1 and 40 μm, and a lateral size of between 5 and 1000 μm, advantageously between 10 and 300 μm.

### BRIEF DESCRIPTION OF THE DRAWINGS

These and other characteristics of the present invention will be apparent from the following description of a preferential form of embodiment, given as a non-restrictive example, with reference to the attached drawings wherein:

FIG. 1 shows, in section, a first form of embodiment of a lighting device according to the present invention;

FIG. 2 shows, in section, a second form of, embodiment of the device according to the invention;

FIGS. 3, 4 and 5 show, from above, in three possible variant solutions, a lighting device according to the invention;

FIG. 6 shows a detail of FIG. 5 on enlarged scale.

### DETAILED DESCRIPTION OF SOME PREFERENTIAL FORMS OF EMBODIMENT OF THE INVENTION

With reference to the attached figures, a lighting device, of the type using organic led technology to generate light, is denoted in its entirety by the reference number 10.

The device 10 according to the invention consists of a multi-layer structure comprising, in a completely integrated form, a multi-point organic led-type light source (OLED), denoted in its entirety by the reference number 11, and an optical system to diffuse and direct the light beams, denoted in its entirety by the reference number 12.

The light source 11 consists of a negative electrode, or cathode, 13 and of a positive electrode, or anode, 14, connected to each other by a circuit comprising an electric feed source 15. Feed can be either in alternating current or direct current. The cathode 13 can consist, for example, of a metallic film made of aluminum-indium alloy. The anode 14 is advantageously made of transparent metal and can consist, for example, of an indium-tin oxide.

In an intermediate position between the cathode 13 and the anode 14 there is a luminescent multi-layer structure formed, in this case, by two layers 16 and 17 of thin-film semi-conductors, one p-type and one n-type, which constitute the active element of the light source.

In one embodiment, the semi-conductor films consist of at least a p-type organic compound, for example naphtha-phenylene benzidine (NPB), and at least an n-type organic compound, for example aluminum hydroxyquinoline (Alq). These specific compounds are cited here only as an example, and are not to be considered in any way restrictive for the possible applications of the present invention.

The use of organic compounds to make semi-conductor light sources is in itself known, and, compared with traditional semi-conductors, allows to increase the efficiency and duration of said sources, also allowing to make lighting devices, displays and screens of extremely limited thickness and with a high capacity to transmit, light.

Between the anode 14 and the upper semi-conductor layer 16 there is, in this case, a stabilizing layer 18, made, for example, of copper phtalocyanine. The anode 14, the cathode 13 and the semi-conductor layers 16 form a matrix whose crossing points, indicated by the reference number 19 in FIGS. 3-5, define the individual points of light emission of the optical lighting device 10.

Particularly in the case when semi-conductors of an organic type are used, between the anode 14 and the transparent substrate 20 there is advantageously a thin protective layer 23 to protect against infiltrations of water, oxygen and other degrading elements.

All this as described heretofore is substantially known in the art for the production of displays and lighting screens.

The optical system to diffuse and direct the light 12, in this case, comprises a transparent substrate 20 of a substantially conventional type, made of plastic or other transparent material, and preferentially of the flexible type, on one face of which is directly made a lenticular element 21 comprising a plurality of micro-lenses 22 cooperating with the multi-point organic led-type light source. Said micro-lenses are obtained by means of molding directly in the substrate. To be more exact, each micro-lens 22 is centered and oriented so as to be displaced (FIG. 6) by a distance “d” of some microns, or tenths of microns, with respect to the relative light source consisting of a relative crossing point 19 or pixel, so as to create a plurality of light emission points focused in a desired manner by means of the specific design of, the lenticular element 21. To be more exact, this shifting of the center of the micro-lens 22 can occur both along one of the two main axes, x or y, of the micro-lens 22, and also with respect to both, so that the distance “d” is defined by components dₓ and d_{y}.

According to the application and the type of light source, the micro-lenses 22 can be of the refractive or diffractive type, but preferentially they are of the diffractive type, since this type of lenses, while it does not reduce the efficiency of the radiation emitted, allows better results in terms of directing the light beam, which can thus be made coherent with the design specifications, even lens by lens.

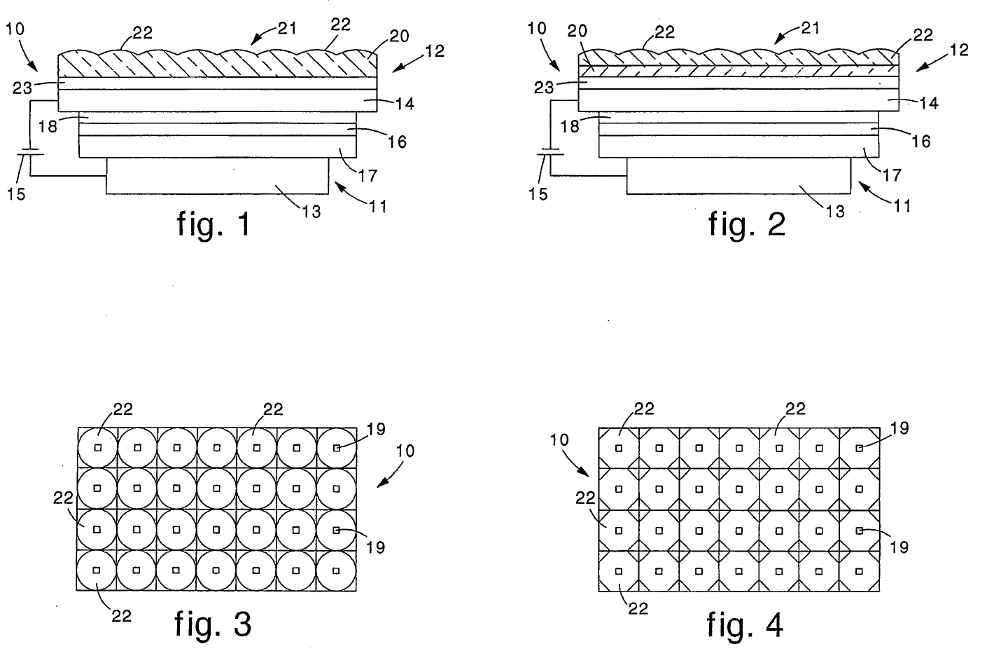

As can be seen in the embodiment shown in FIG. 1, the lenses 22 are made directly on the transparent substrate 20, for example by means of molding, either cold or hot, of its outer surface by means of a suitable pre-formed mold. The preferential embodiment, which as we have said uses a hot-embossing technique to make the lenses directly on the substrate, allows to achieve, on an industrial scale, large quantities of micro-optical systems characterized by micrometric precision both with regard to the positioning with respect to the relative light sources and also with regard to the geometry of the corrugations proposed for shaping the beam. The use of molds made of nickel, whose impressions are conformed according to design specifications, constitutes a peculiarity of the present invention which achieves considerable advantages in that it saves time and money, the material is easier to find, and results are standardized.

Therefore, although in the state of the art it is known to make the micro-optical system by molding directly onto a face of a transparent substrate, it is not known to make said micro-optical system on a substrate on whose opposite face-an organic led light source is directly generated.

Said molding is advantageously performed before the light source 11 is associated on the other face of the substrate 20. According to a variant, the lenses 22 are molded on the outer face of the substrate 20 after the light source has already been associated with the other face of the substrate 20.

By obtaining the lenticular element 21 by means of molding onto one face of the transparent substrate 20, we in fact achieve an integrated micro-optical system to diffuse the light beams, suitable to create particular effects, both aesthetically and in directing the light beam, with a distribution of the light intensity which cannot be achieved with luminous devices used at present.

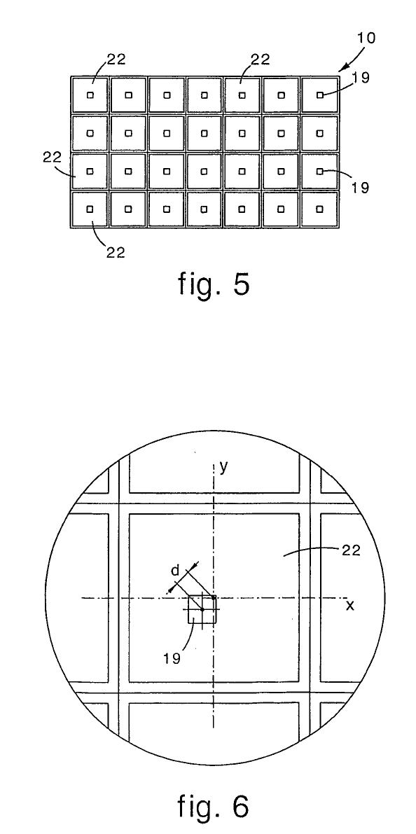

According to the use and aesthetic effect to be obtained, the lenses 22 can be substantially of any shape, for example circular (FIG. 3), hexagonal (FIG. 4), square (FIG. 5), or any other shape, provided they are suitable to be positioned in a desired manner in correspondence with the crossing points 19, or pixels, advantageously with a desired shift “d”, corresponding to the individual light sources.

It is clear, however, that modifications and/or additions of parts may be made to the lighting device 10, and the method to make lighting devices, as described heretofore, without departing from the spirit and scope of the present invention.

1. Lighting device comprising
an at least partly transparent substrate, and
a light source made integrally on a first face of said substrate, said light source including at least a positive electrode and a negative electrode to supply electric power, interacting with each other and between which at least a luminescent layer of the organic-led type . (OLED) is located,
said substrate being able to diffuse the light generated by said organic led luminescent layer,
a lenticular optical element being associated on the opposite face of said substrate said lenticular optical element to diffuse the light beam emitted by said light source comprising a plurality of micro-lenses directly molded, by means of a pre-formed mold, on a second face of said substrate opposite to the first face to constitute, with said organic led light source, an integrated structure to generate, emit and direct the light, each one of said micro-lenses being coupled with a relative point of light emission of said light source to direct and shape the relative light beam emitted, wherein each said micro-lens has its relative center located shifted with respect to the relative point of light emission.

2. Device as in claim 1, wherein each of said points of light emission consists of crossing points, or pixels, between said positive electrode and said negative electrode.

3. Device as in claim 1, wherein each of said points of light emission comprises crossing points, or pixels, between said positive electrode and said negative electrode.

4. Device as in claim 1, wherein said shift is achieved with respect to one and/or the other of the main axes (x, y) of the relative micro-lens.

5. Device as in claim 1, wherein at least some of said micro-lenses are of the diffractive type to divert and direct the ray of light emitted by the relative point of light emission.

6. Device as in claim 1, wherein said micro-lenses have a thickness of between 1 and 100 micron (μm).

7. Device as in claim 1, wherein said micro-lenses have a lateral size of between 5 and 1000 micron.

8. Device as in claim 1, wherein the micro-lenses of a relative lenticular optical element are all equal to each other.

9. Device as in claim 1, wherein the micro-lenses of a relative lenticular optical element are different from each other to direct and shape the light beam emitted by the relative point of light emission.

10. Device as in claim 1, wherein said substrate is made of plastic material.

11. Device as in claim 1, wherein said substrate is made of at least partly flexible glass.

12. Method to produce lighting devices comprising at least an organic led-type multi-layer light source and at least an optical system to diffuse and direct the light beams, comprising at least an at least partly transparent substrate, at least a lenticular optical element being associated with one face of said substrate opposite to the face where said light source is provided, comprising the steps of directly molding said lenticular optical element, by means a pre-formed mold, on said substrate to obtain a plurality of micro-lenses each of which is coupled with micrometric precision at least with regard to the positioning with respect to an individual point of emission of said organic led light source.

13. Method as in claim 12, wherein the molding is performed with nickel molds on which the impressions corresponding to the lenticular optical matrix are obtained with the step and repeat technique.

14. Method as in claim 12, wherein said molding is performed hot.

15. Method as in claim 14, wherein the hot molding is performed on an industrial scale with a hot-embossing technique.

16. Method as in claim 12, wherein said molding is performed cold.

17. Method as in claim 12, wherein the micro-lenses of a same lenticular optical element are all made equal to each other.

18. Method as in claim 12, wherein the micro-lenses of a same lenticular optical element are made different from each other to perform specific functions of directing and shaping the light beam emitted by the relative point of light emission.

19. Method as in claim 12, wherein said molding takes place after said substrate has been associated with the light source .

20. Method as in claim 12, wherein said molding takes place before the light source has been associated with said substrate.

21. Method as in claim 12, wherein the micro-lenses of said lenticular optical element are positioned shifted with respect to the corresponding crossing point, or pixel, between a positive electrode and a negative electrode.

22. Device as in claim 1, wherein said micro-lenses have a thickness of between 1 and 40 micron (μm).

23. Device as in claim 1, wherein said micro-lenses have a lateral size of between 10 and 300 micron (μm).
